(19) United States
(12) Patent Application Publication
(10) Pub. No.: US 2013/0292818 A1
(43) Pub. Date: Nov. 7, 2013

(54) SEMICONDUCTOR CHIP, SEMICONDUCTOR PACKAGE HAVING THE SAME, AND STACKED SEMICONDUCTOR PACKAGE USING THE SEMICONDUCTOR PACKAGE

(71) Applicant: Seung Hee JO, Yongin-si (KR)

(72) Inventor: Seung Hee JO, Yongin-si (KR)

(73) Assignee: SK HYNIX INC., Icheon-si (KR)

(21) Appl. No.: 13/614,869

(22) Filed: Sep. 13, 2012

(30) Foreign Application Priority Data
May 3, 2012 (KR) 10-2012-0047060

(51) Int. Cl. H01L 23/48

(52) U.S. Cl. 257/737; 257/E23.021

(57) ABSTRACT

A semiconductor package includes a semiconductor chip having a front surface and a back surface; through electrode formed in the semiconductor chip to pass through the front surface and the back surface and having a first end which is disposed on the front surface and a second end which is disposed on the back surface; and back-side bump formed over the second end of the through electrode and including an embedded pattern which is formed over a portion of the second end of the through electrode and a conductive pattern which is formed over the embedded pattern and a remaining portion of the second end of the through is electrode and having a convex sectional shape.

### CROSS-REFERENCE TO RELATED APPLICATIONS

The present application claims priority to Korean patent application number 10-2012-0047060 filed on May 3, 2012, in the Korean Intellectual Property Office, which is incorporated herein by reference in its entirety.

### BACKGROUND OF THE INVENTION

1. Field of Invention

The present invention relates to a semiconductor package, and more particularly, to a semiconductor chip which improves reliability by changing the shapes of back-side bumps, a semiconductor package having the same, and a stacked semiconductor package using the semiconductor package.

2. Description of the Related Art

Packaging technologies trend toward reduction of an overall size and achievement of a high capacity of semiconductor packages. In particular, although a high capacity may be achieved by realizing a highly integrated semiconductor device, realization of a highly integrated semiconductor device is difficult and has a limitation in itself. Thus, high capacity is being achieved by mounting at least two semiconductor chips in one package.

In a stacked semiconductor package realized by mounting at least two semiconductor chips, signal transfer to the respective stacked semiconductor chips is generally performed by metal wires. However, in the case of the stacked semiconductor package realized using the metal wires, disadvantages are caused in that a driving speed is slow since a signal transfer length is long and an overall size increases since additional areas are required for wire bonding.

Under this situation, in a recently developed stacked semiconductor package, through electrodes are used for electrical connection between a substrate and stacked semiconductor chips. The stacked semiconductor package using the through electrodes has a structure in which through electrodes are formed in respective semiconductor chips to be stacked, and the semiconductor chips formed with the through electrodes are physically and electrically connected with one another through interconnection of the through electrodes and with a substrate.

In order to interconnect the through electrodes, bumps are generally formed on both ends of the through electrodes. When stacking the semiconductor chips through junction of the bumps, an NCP (non-conductive paste) or an NCF (non-conductive film) is interposed between the semiconductor chips.

Here, in order to achieve high capacity stacking, it is necessary to decrease the gap between semiconductor chips. In order to decrease the gap between semiconductor chips, the height of bumps should be decreased. If bump heights are decreased, however, a bump dimple occurs by the geometry of a bottom layer, and, due to this fact, the NCP or NCF is likely to be trapped in the dimple when joining the semiconductor chips with each other, whereby a junction strength between the semiconductor chips may be degraded and a fail may result. In particular, while there is typically no dimple on the bumps on the front ends of the through electrodes (hereinafter, referred to as “front-side bumps”) because the front-side bumps are formed through soldering, it is difficult to remove dimples from the bumps on the back ends of the through electrodes (hereinafter, referred to as “back-side bumps”).

### BRIEF SUMMARY OF THE INVENTION

An embodiment of the present invention is directed to a semiconductor chip which can prevent the occurrence of a bump dimpling phenomenon by changing the structure of back-side bumps.

Also, an embodiment of the present invention is directed to a semiconductor package having the semiconductor chip.

Further, an embodiment of the present invention is directed to a stacked semiconductor package which can prevent bump dimpling by changing the structure of back-side bumps, while spaces to be occupied by bumps are reduced, thereby preventing reliability from being degraded.

In one embodiment of the present invention, a semiconductor chip includes bumps formed over pads as connection members to an external circuit, the bumps including: embedded pattern formed over a portion of the pad; and a conductive pattern formed over the embedded pattern and a remaining portion of the pad and having a convex sectional shape.

The semiconductor chip may further include an insulation pattern formed over the semiconductor chip in such a way as to expose the pads.

The embedded pattern may be disposed over a center portion of the pad.

The semiconductor chip may further include a seed metal interposed between the pad and the embedded pattern and between the pad and the conductive pattern.

The embedded pattern may be formed of the same kind of metal as the seed metal.

The conductive pattern may include a plating layer which is grown by using the seed metal and the embedded pattern as a seed.

The semiconductor chip may further include a seed metal interposed between the pad and the conductive pattern and between the embedded pattern and the conductive pattern.

The embedded pattern may be formed of a dielectric substance.

The conductive pattern may include a plating layer which is grown by using the seed metal as a seed.

The pad may include bonding pad or redistribution pad.

In another embodiment of the present invention, a semiconductor package includes: a semiconductor chip having a front surface and a back surface; through electrode formed in the semiconductor chip to pass through the front surface and the back surface and having a first end which is disposed on the front surface and a second end which is disposed on the back surface; and back-side bump formed over the second end of the through electrode and including an embedded pattern which is formed over a portion of the second end of the through electrode and a conductive pattern which is formed over the embedded pattern and a remaining portion of the second end of the through electrode and having a convex sectional shape.

The semiconductor package may further include an insulating pattern formed over the back surface of the semiconductor chip in such a way as to expose the second end of the through electrode.

The semiconductor package may further include front-side bump formed over the first ends of the through electrode.

The semiconductor package may further include front-side bumps formed over the first end of the through electrode.

The embedded pattern may be disposed over a center portion of the exposed second ends of the through electrodes.

The back-side bump may further include a seed metal interposed between the second end of the through electrode and the embedded pattern and between the second end of the through electrode and the conductive pattern.

The embedded pattern may be formed of the same kind of metal as the seed metal.

The conductive pattern may include a plating layer which is grown by using the seed metal and the embedded pattern as a seed.

The semiconductor package may further include a seed metal interposed between the second end of the through electrode and the conductive pattern and between the embedded pattern and the conductive pattern.

The embedded pattern may be formed of a dielectric substance.

The conductive pattern may include a plating layer which is grown by using the seed metal as a seed.

In still another embodiment of the present invention, a stacked semiconductor package includes: a first semiconductor package including a semiconductor chip having a front surface and a back surface, through electrode formed in the semiconductor chip to pass through the front surface and the back surface and having a first end which is disposed on the front surface and a second end which is disposed on the back surface, front-side bump formed over the first end of the through electrode, and back-side bump formed over the second end of the through electrode and including an embedded pattern which is formed over a portion of the second end of the through electrode and a conductive pattern which is formed over the embedded pattern and a remaining portion of the second end of the through electrode and having a convex sectional shape; at least one second semiconductor package stacked over the first semiconductor package and having a substantially configuration as the first semiconductor package, back-side bump of the second semiconductor package being connected with front-side bump of an underlying semiconductor package; and a third semiconductor package stacked over a second semiconductor package positioned uppermost among stacked second semiconductor packages and having back-side bump which are connected with front-side bump of the uppermost second semiconductor package and including an embedded pattern and a conductive pattern with a convex sectional shape.

The stacked semiconductor package may further include insulation patterns formed over respective back surfaces of the semiconductor chip in such a way as to expose the second ends of the through electrodes.

The embedded pattern may be disposed over a center portion of the exposed second end of the through electrode.

The back-side bump may further include a seed metal interposed between the second end of the through electrode and the embedded pattern and between the second end of the through electrode and the conductive pattern.

The embedded pattern may be formed of the same kind of metal as the seed metal.

The conductive pattern may include a plating layer which is grown by using the seed metal and the embedded pattern as a seed.

The stacked semiconductor package may further include a seed metal interposed between the second end of the through electrode and the conductive pattern and between the embedded pattern and the conductive pattern.

The embedded pattern may be formed of a dielectric substance.

The conductive pattern may be included a plating layer which is grown by using the seed metal as a seed.

The stacked semiconductor package may further include connection members interposed between the front-side bump of the first semiconductor package and the back-side bump of the second semiconductor package and between front-side bump of the second semiconductor package and the back-side bump of the third semiconductor package.

The stacked semiconductor package may further include underfill members filled in spaces between the stacked first and second semiconductor packages and between the stacked second and third semiconductor packages.

The stacked semiconductor package may further include a structural body supporting the stacked first and second semiconductor packages and having on one surface thereof connection electrodes which are electrically connected with the through electrode of the first semiconductor package, through the back-side bump of the first semiconductor package.

The structural body may include any one of a printed circuit board, an interposer and a fourth semiconductor package.

The stacked semiconductor package may further include: a molding member formed on the one surface of the structural body to cover the stacked first and second semiconductor packages; and external connection terminals disposed on the other surface of the structural body which faces away from the one surface.

### BRIEF DESCRIPTION OF THE DRAWINGS

FIGS. 1 and 2 are cross-sectional views illustrating semiconductor chips in accordance with an embodiment of the present invention.

FIG. 3 is a cross-sectional view illustrating a semiconductor package in accordance with another embodiment of the present invention.

FIGS. 4 and 5 are cross-sectional views illustrating stacked semiconductor packages in accordance with another embodiment of the present invention.

FIG. 6 is a perspective view illustrating an electronic apparatus including the semiconductor package according to the present invention.

FIG. 7 is a block diagram showing an example of an electronic system including the semiconductor package according to the present invention.

### DESCRIPTION OF SPECIFIC EMBODIMENTS

Hereafter, specific embodiments of the present invention will be described in detail with reference to the accompanying drawings.

It is to be understood herein that the drawings are not necessarily to scale and in some instances proportions may have been exaggerated in order to more clearly depict certain features of the invention.

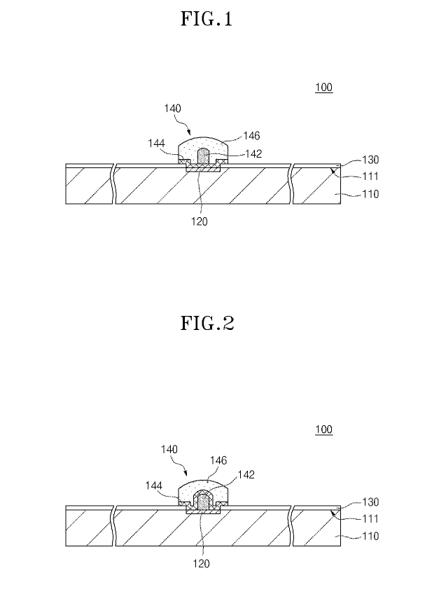

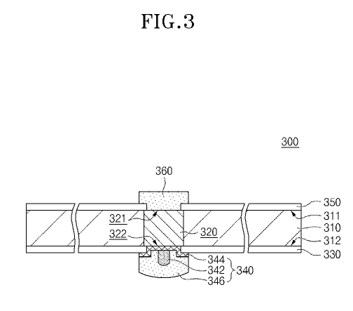

FIGS. 1 and 2 are cross-sectional views illustrating semiconductor chips in accordance with an embodiment of the present invention.

Referring to FIGS. 1 and 2, a semiconductor chip 100 in accordance with an embodiment of the present invention includes a semiconductor chip body 110, pads 120 and bumps 140. Also, the semiconductor chip 100 in accordance with the embodiment of the present invention further includes an insulation pattern 130 which is formed in such a way as to expose the pads 120.

The semiconductor chip body 110 has, for example, a rectangular hexahedral shape and includes an active surface 111. The semiconductor chip body 110 may be formed with a circuit unit therein.

For example, the pads 120 may be bonding pads. In this case, the pads 120 are disposed on the active surface 111 of the semiconductor chip body 110 and are electrically connected with the circuit unit formed in the semiconductor chip body 110.

The pads 120 may also be redistribution pads. In acting as redistribution pads, while not shown, the pads 120 may be parts of redistribution lines and may be disposed not only on the active surface 111 of the semiconductor chip body 110 but also on a surface of the semiconductor chip body 110 which faces away from the active surface 111.

The bumps 140 include embedded patterns 142 which are formed on portions of the pads 120. The bumps 140 may also include conductive patterns 146 which are formed on the embedded patterns 142 and the remaining portions of the pads 120 and have a convex sectional shape.

In one embodiment, as shown in FIG. 1, the bumps 140 further include a seed metal 144 which is interposed between the pads 120 and the embedded patterns 142, and interposed between the pads 120 and the conductive patterns 146. The embedded patterns 142 are formed of a substantially similar and/or same metal as the seed metal 144. The conductive patterns 146 are constituted by a plating layer which is grown by using the seed metal 144 and the embedded patterns 142 as a seed, for example, a copper plating layer.

In another embodiment, as shown in FIG. 2, the bumps 140 further include a seed metal 144 which is interposed between the pad 120 and the conductive patterns 146 and between the embedded patterns 142 and the conductive patterns 146. The embedded patterns 142 are formed of a dielectric substance, and the conductive patterns 146 are constituted by a plating layer which is grown by using the seed metal 144 as a seed, for example, a copper plating layer.

In the semiconductor chip in accordance with the present embodiment, conductive patterns constituted by a plating layer may have a convex sectional shape due to the presence of embedded patterns. Accordingly, bumps including the embedded patterns and the conductive patterns may have a convex sectional shape when viewed in their entireties.

As a consequence, because the semiconductor chip in accordance with the present embodiment include bumps with the convex sectional shape, when the semiconductor chip is mounted to an external circuit by way of such bumps, a dimple does not occur in the bumps, and thus, mounting reliability of the semiconductor chip with respect to the external circuit may be improved.

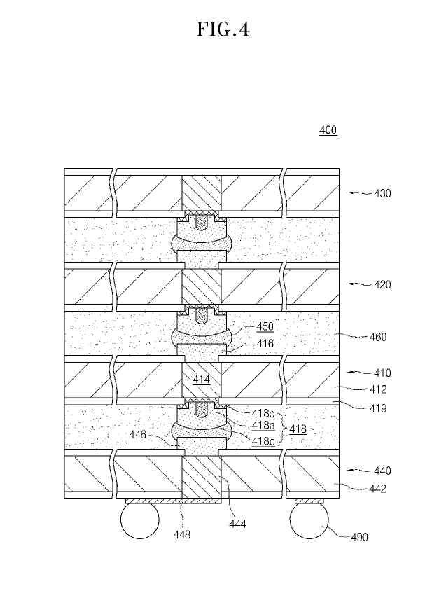

FIG. 3 is a cross-sectional view illustrating a semiconductor package in accordance with another embodiment of the present invention.

Referring to FIG. 3, a semiconductor package 300 in accordance with another embodiment of the present invention includes a semiconductor chip 310, through electrodes 320, and back-side bumps 340.

The semiconductor chip 310 has a front surface 311 and a back surface 312 which faces away from the front surface 311. While not shown, the semiconductor chip 310 includes a plurality of bonding pads which are disposed on the front surface 311 thereof, and a circuit unit which is formed therein. The plurality of bonding pads may be arranged in one line or two lines on the center portion of the front surface 311 of the semiconductor chip 310. In another variation of this embodiment, the plurality of bonding pads may be arranged in one line or two lines on at least one of one edge of the front surface 311 and the other edge of the front surface 311 opposite to the one edge, or the plurality of bonding pads may be arranged in one line or two lines along the edges of the front surface 311. The circuit unit is formed in an inside portion of the semiconductor chip 310 adjacent to the front surface 311, and may include, for example, a data storage section for storing data and a data processing section for processing data.

The through electrodes 320 are formed to pass through the front surface 311 and the back surface 312 of the semiconductor chip 310. The through electrodes 320 have first ends 321 which are disposed on the front surface 311 of the semiconductor chip 310 and second ends 322 which are disposed on the back surface 312 of the semiconductor chip 310. While not shown, the through electrodes 320 are electrically connected with the bonding pads which are disposed on the front surface 311 of the semiconductor chip 310, in one-to-one correspondence. To this end, the through electrodes 320 are formed to pass through the corresponding bonding pads such that the first ends 321 thereof may be electrically connected directly with the corresponding bonding pads. In another variation of this embodiment, the through electrodes 320 may be formed to pass through portions of the semiconductor chip which are adjacent to the corresponding bonding pads, and the first ends 321 of the through electrodes 320 may be electrically connected with the corresponding bonding pads by redistribution lines and the likes.

The semiconductor package 300 in accordance with the present embodiment further includes an insulation pattern 330 which are formed on the back surface 312 of the semiconductor chip 310 in such a way as to expose the second ends 322 of the through electrodes 320. The insulation pattern 330 may be formed in such a way as to partially expose the second ends 322 of the through electrodes 320 as shown in the drawing. In another variation of this embodiment, the insulation pattern 330 may be formed in such a way as to entirely expose the second ends 322 of the through electrodes 320.

The back-side bumps 340 are formed on exposed parts of the second ends 322 of the through electrodes 320 and on portions of the insulation pattern 330 which are adjacent to the exposed parts of the second ends 322 of the through electrodes 320. In detail, the back-side bumps 340 include embedded patterns 342 which are formed on portions of the exposed parts of the second ends 322 of the through electrodes 320 and conductive patterns 346 which are formed on the embedded patterns 342, the remaining portions of the exposed parts of the second ends 322 of the through electrodes 320 and the portions of the insulation pattern 330 which are adjacent to the exposed parts of the second ends 322 of the through electrodes 320.

In the present embodiment, the embedded patterns 342 are formed on the portions of the exposed parts of the second ends 322 of the through electrodes 320 to prevent occurrence of a bump dimple. The embedded patterns 342 may be formed to be disposed centrally on the exposed parts of the second ends 322 of the through electrodes 320. The embedded patterns 342 are formed of, for example, a metal. As will be clearly described later, the embedded patterns 342 are formed of a substantially similar and/or same metal as a seed metal for forming the conductive patterns 346. The embedded patterns 342 made of such a metal may be formed through, for example, thermal compression similar to wire bonding.

In one embodiment, as shown in FIG. 3, the back-side bumps 340 of the semiconductor package 300 further include a seed metal 344 which is interposed between the second ends 322 of the through electrodes 320 and the embedded patterns 342 and between the second ends 322 of the through electrodes 320 and the conductive patterns 346. The embedded patterns 342 are formed of a substantially similar and/or same metal as the seed metal 344, and the conductive patterns 346 are constituted by a plating layer which is grown by using the seed metal 344 and the embedded patterns 342 as a seed, for example, a copper plating layer.

In another embodiment, while not shown in a drawing, the back-side bumps 340 of the semiconductor package 300 further include a seed metal 344 which is interposed between the second ends 322 of the through electrodes 320 and the conductive patterns 346 and between the embedded patterns 342 and the conductive patterns 346. The embedded patterns 342 are formed of a dielectric substance, and the conductive patterns 346 are constituted by a plating layer which is grown by using the seed metal 344 as a seed, for example, a copper plating layer.

Moreover, the semiconductor package 300 in accordance with the present embodiment further includes an additional insulation pattern 350 which is formed on the front surface 311 of the semiconductor chip 310 in such a way as to expose the first ends 321 of the through electrodes 320 and front-side bumps 360 which are formed on parts of the first ends 321 of the through electrodes 320 that are exposed.

In the semiconductor package in accordance with the present embodiment as described above, back-side bumps have a convex sectional shape due to the presence of embedded patterns. Hence, when the semiconductor package is mounted to an external circuit by way of such bumps, a dimple does not occur in the bumps, and thus, the semiconductor package in accordance with the present embodiment has improved mounting reliability.

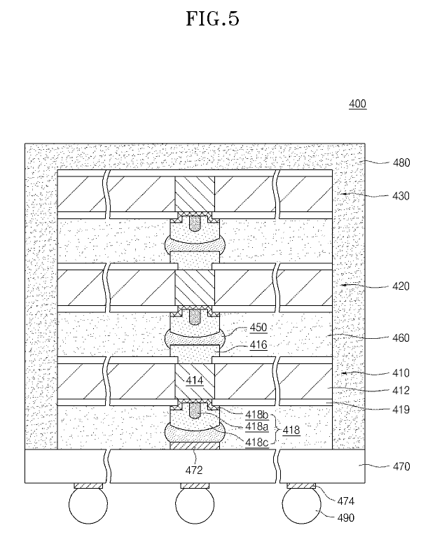

FIGS. 4 and 5 are cross-sectional views illustrating stacked semiconductor packages in accordance with another embodiment of the present invention.

Referring to FIGS. 4 and 5, a stacked semiconductor package 400 in accordance with another embodiment of the present invention includes a first semiconductor package 410 and at least one second semiconductor package 420. Also, the stacked semiconductor package 400 in accordance with another embodiment of the present invention further includes an underfill member 460 such as an NCP (non-conductive paste) or an NCF (non-conductive film) filled in the space between the stacked semiconductor packages 410 and 420.

The first semiconductor package 410 includes a semiconductor chip 412 having a front surface and a back surface which faces away from the front surface, through electrodes 414 formed in the semiconductor chip 412 to pass through the front surface and the back surface and having first ends which are disposed on the front surface and second ends which are disposed on the back surface, front-side bumps 416 formed on the first ends of the through electrodes 414, and back-side bumps 418 formed on the second ends of the through electrodes 414. The bumps 416 and 418 may be configured be connection members. Also, the first semiconductor package 410 further includes an insulation pattern 419 which is formed on the back surface in such a way as to expose the second ends of the through electrodes 414.

The back-side bumps 418 include embedded patterns 418a which are disposed on portions of the second ends of the through electrodes 414 and conductive patterns 418c which are disposed on the embedded patterns 418a and the remaining portions of the second ends of the through electrodes 414. The conductive patterns 418c may have a convex sectional shape. The embedded patterns 418a may be disposed on the center portions of exposed parts of the second ends of the through electrodes 414.

In one embodiment, the back-side bumps 418 further include a seed metal 418b which is interposed between the second ends of the through electrodes 414 and the embedded patterns 418a and between the second ends of the through electrodes 414 and the conductive patterns 418c. The embedded patterns 418a may be formed of a substantially similar and/or same metal as the seed metal 418b, and the conductive patterns 418c are constituted by a plating layer which is grown by using the seed metal 418b and the embedded patterns 418a as a seed.

In another embodiment, while not shown in a drawing, the bumps 418 further include a seed metal 418b which is interposed between the second ends of the through electrodes 414 and the conductive patterns 418c and between the embedded patterns 418a and the conductive patterns 418c. The embedded patterns 418a are formed of a dielectric substance, and the conductive patterns 418c are constituted by a plating layer which is grown by using the seed metal 418b as a seed.

At least one second semiconductor package 420 is stacked on the first semiconductor package 410. In the present embodiment, one second semiconductor package 420 is stacked. The second semiconductor package 420 has a substantially similar and/or same configuration as the first semiconductor package 410. In particular, the back-side bumps 418 of the second semiconductor package 420 are electrically connected with the front-side bumps 416 of the underlying first semiconductor package 410 by connection members 450, for example, such as solders.

While not shown in a drawing, at least two second semiconductor packages, such as semiconductor package 420, may be stacked. When at least two second semiconductor packages 420 are stacked, the connection members 450 may interposed between and electrically connect the back-side bumps 418 of a higher positioned semiconductor package with the front-side bumps 416 of a lower positioned semiconductor package.

The stacked semiconductor package 400 in accordance with the present embodiment further includes a third semiconductor package 430 which is stacked on the second semiconductor package 420 or on the second semiconductor package 420 positioned uppermost among stacked second semiconductor packages 410 and 420. The third semiconductor package 430 may have a substantially similar and/or same configuration as the first and second semiconductor packages 410 and 420 except that front-side bumps are not formed on the first ends of the through electrodes 414. That is to say, the back-side bumps 418 of the third semiconductor package 430 are electrically connected with the front-side bumps 416 of the underlying second semiconductor package 420 by the connection members 450.

The third semiconductor package 430 may include a substantially similar and/or same kind of semiconductor chip as the first and second semiconductor packages 410 and 420, or the third semiconductor package 430 may include a different kind of semiconductor chip from the first and second semiconductor packages 410 and 420, for example, a driving chip.

The stacked semiconductor package 400 in accordance with the present embodiment further includes a structural body which is disposed underneath the first semiconductor package 410.

The structural body may be a fourth semiconductor package 440 having through electrodes 444 as connection electrodes and front-side bumps 446, as shown in FIG. 4. The fourth semiconductor package 440 includes a semiconductor chip 442 having a front surface and a back surface which faces away from the front surface, through electrodes 444 formed to pass through the front surface and the back surface and having first ends which are disposed on the front surface and second ends which are disposed on the back surface. The fourth semiconductor package 440 may also include the front-side bumps 446 formed on the first ends of the through electrodes 444, and redistribution lines 448 formed on the back surface of the semiconductor chip 442 such that an end of the redistribution lines 448 are connected with the second ends of the through electrodes 444. The fourth semiconductor package 440 may include a substantially similar and/or same or a different kind of memory chip as or from the first, second and third semiconductor packages 410, 420 and 430.

The structural body may be a printed circuit board 470 having connection electrodes such as bond fingers, as shown in FIG. 5. The printed circuit board 470 includes bond fingers 472 disposed on the upper surface thereof as connection electrodes and ball lands 474 disposed on the lower surface thereof.

While not shown in a drawing, the structural body may be an interposer having connection electrodes.

The stacked semiconductor package 400 in accordance with the present embodiment further includes external connection terminals 490, such as solder balls, which are attached to the redistribution lines 448 of the fourth semiconductor package 440, as shown in FIG. 4.

The stacked semiconductor package 400 in accordance with the present embodiment may further include a molding member 480 which is formed on an upper surface of the printed circuit board 470 to cover the stacked first, second and third semiconductor packages 410, 420 and 430. The molding member 480 may be formed over the external connection terminals 490, such as solder balls, which are attached to the ball lands 474 disposed on the lower surface of the printed circuit board 470, as shown in FIG. 5.

In the stacked semiconductor package in accordance with the present embodiment, a bump dimple phenomenon does not occur because back-side bumps have a convex sectional shape due to the presence of embedded patterns. Accordingly, when stacking first, second and third semiconductor packages or when stacking second semiconductor packages, a failure that an underfill member such as an NCP or an NCF is trapped in the back-side bumps does not result.

As a consequence, in the stacked semiconductor package in accordance with the present embodiment, since a junction strength between semiconductor packages is not degraded and a failure does not result, the characteristics and the reliability of the stacked semiconductor package may be significantly improved.

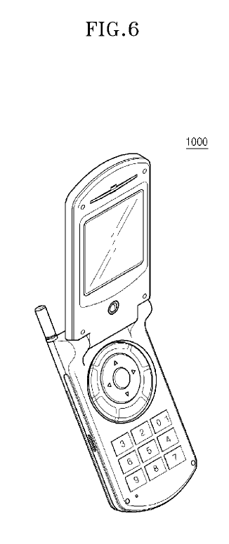

FIG. 6 is a perspective view illustrating an electronic apparatus including the semiconductor package according to the present invention.

Referring to FIG. 6, the semiconductor package according to an embodiment of the present invention may be implemented in an electronic apparatus 1000 such as a mobile phone. Because the semiconductor package according to the embodiment of the present invention accomplishes excellent mounting reliability, advantages are provided in improving the characteristics of the electronic apparatus 1000. The electronic apparatus 1000 is not limited to the mobile phone shown in FIG. 6, and may include various electronic appliances such as a mobile electronic appliance, a laptop computer, a notebook computer, a portable multimedia player (PMP), an MP3 player, a camcorder, a web tablet, a wireless phone, a navigator, a personal digital assistant (PDA), and so forth.

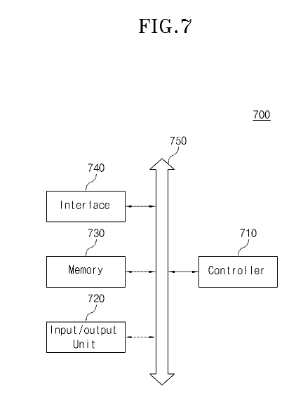

FIG. 7 is a block diagram showing an example of an electronic system including the semiconductor package according to the present invention.

Referring to FIG. 7, an electronic system 700 may include a controller 710, an input/output unit 720, and a memory 730. The controller 710, the input/output unit 720 and the memory 730 may be coupled with one another through a bus 750. The bus 750 may be a path through which data moves.

For example, the controller 710 may include at least any one of at least one microprocessor, at least one digital signal processor, at least one microcontroller, and logic devices capable of performing the same functions as these components. The controller 710 and the memory 730 may include the semiconductor package according to an embodiment of the present invention.

The input/output unit 720 may include at least one selected among a keypad, a keyboard, a display device, and so forth.

The memory 730 is a device for storing data. The memory 730 may store data and/or commands to be executed by the controller 710, and so forth. The memory 730 may include a volatile memory device and/or a nonvolatile memory device. Also, the memory 730 may be formed as a flash memory. For example, a flash memory to which the technology of the present invention is applied may be mounted to an information processing system such as a mobile appliance or a desk top computer. The flash memory may be constituted by a solid state drive (SSD). In this case, the electronic system 700 may stably store a large amount of data in a flash memory system.

The electronic system 700 may further include an interface 740 configured to transmit and receive data to and from a communication network. The interface 740 may be a wired or wireless type. For example, the interface 740 may include an antenna or a wired or wireless transceiver.

Moreover, while not shown, a person skilled in the art will readily appreciate that the electronic system 700 may be additionally provided with an application chipset, a camera image processor (CIP), an input/output device, etc.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor chip including bumps formed over pads as connection members to an external circuit, the bumps comprising:
a embedded pattern formed over a portion of the pad; and
a conductive pattern formed over the embedded pattern and a remaining portion of the pad and having a convex sectional shape.

2. The semiconductor chip according to claim 1, further comprising:
an insulation pattern formed over the semiconductor chip in such a way as to expose the pads.

3. The semiconductor chip according to claim 1, wherein the embedded pattern is disposed over a center portion of the pad.

4. The semiconductor chip according to claim 1, further comprising:
a seed metal interposed between the pad and the embedded pattern and between the pad and the conductive pattern.

5. The semiconductor chip according to claim 4, wherein the embedded pattern is formed of the same kind of metal as the seed metal.

6. The semiconductor chip according to claim 4, wherein the conductive pattern comprises a plating layer which is grown by using the seed metal and the embedded pattern as a seed.

7. The semiconductor chip according to claim 1, further comprising:
a seed metal interposed between the pad and the conductive pattern and between the embedded pattern and the conductive to pattern.

8. The semiconductor chip according to claim 7, wherein the embedded pattern is formed of a dielectric substance.

9. The semiconductor chip according to claim 7, wherein the conductive pattern comprises a plating layer which is grown by using the seed metal as a seed.

10. The semiconductor chip according to claim 1, wherein the pad comprises bonding pad or redistribution pad.

11. A semiconductor package comprising:
a semiconductor chip having a front surface and a back surface;
through electrode formed in the semiconductor chip to pass through the front surface and the back surface and having a first end which is disposed on the front surface and a second end which is disposed on the back surface; and
back-side bump formed over the second end of the through electrode and including an embedded pattern which is formed over a portion of the second end of the through electrode and a conductive pattern which is formed over the embedded pattern and a remaining portion of the second end of the through electrode and having a convex sectional shape.

12. The semiconductor package according to claim 11, further comprising:
an insulating pattern formed over the back surface of the semiconductor chip in such a way as to expose the second end of the through electrode.

13. The semiconductor package according to claim 11, further comprising:
front-side bump formed over the first ends of the through electrode.

14. The semiconductor package according to claim 11, wherein the embedded pattern is disposed over a center portion of the exposed second end of the through electrode.

15. The semiconductor package according to claim 11, wherein the back-side bump further comprise:
a seed metal interposed between the second end of the through electrode and the embedded pattern and between the second end of the through electrode and the conductive pattern.

16. The semiconductor package according to claim 15, wherein the embedded pattern is formed of the same kind of metal as the seed metal.

17. The semiconductor package according to claim 11, wherein the conductive pattern comprises a plating layer which is grown by using the seed metal and the embedded pattern as a seed.

18. The semiconductor package according to claim 11, further comprising:
a seed metal interposed between the second end of the through electrode and the conductive pattern and between the embedded pattern and the conductive pattern.

19. The semiconductor package according to claim 18, wherein the embedded pattern is formed of a dielectric substance.

20. The semiconductor package according to claim 18, wherein the conductive pattern comprises a plating layer which is grown by using the seed metal as a seed.
